(19) United States
(12) Patent Application Publication
(10) Pub. No.: US 2003/0025143 A1
(43) Pub. Date: Feb. 6, 2003

(54) Metal-insulator-metal capacitor and method of manufacture

(76) Inventors: Benjamin Szu-Min Lin, Hsinchu (TW); Osbert Cheng, Hsinchu (TW)

Correspondence Address: CHARLES C.H. WU & ASSOCIATES, Suite 710, 7700 IRVINE CENTER DRIVE, Irvine, CA, 92618-3043, US

(21) Appl. No.: 09/920,066

(22) Filed: Aug. 1, 2001

(51) Int. Cl. H01L 27/108

(52) U.S. Cl. 257/303

(57) ABSTRACT

A method of forming a metal-insulator-metal capacitor. A substrate is provided and then a first dielectric layer is formed over the substrate. The first dielectric layer is patterned to form a first opening for forming a desired lower electrode and a second opening for forming a desired conductive line. A first metallic layer conformal to the exposed surface of the first opening and completely filling the second opening is formed. A conformal capacitor dielectric layer is formed over the first metallic layer and then a second dielectric layer is formed over the capacitor dielectric layer. The second dielectric layer is patterned to form a third opening above the first opening and a fourth opening above the second opening. The third opening exposes a portion of the capacitor dielectric layer and the fourth opening exposes a portion of the first metallic layer. Finally, a second metallic layer that completely fills the third opening and the fourth opening is formed.

### BACKGROUND OF THE INVENTION

1. Field of Invention

The present invention relates to a type of capacitor. More particularly, the present invention relates to a metal-insulator-metal (MIM) capacitor and its method of manufacture.

2. Description of Related Art

Following the fabrication of highly integrated deep sub-micron devices in integrated circuits, dimension of individual device is reduced considerably. Correspondingly, area available for forming a capacitor is also reduced. However, the capacitance of a capacitor depends very much on the overall surface area between a lower electrode and an upper electrode. At present, the two principle methods for increasing or maintaining the capacitance of a capacitor despite a reduction in surface area are used. They include the selection of a dielectric material having a high dielectric constant and the increase in overall surface area by convoluting the lower electrode of the capacitor.

When a high dielectric constant material is used in the capacitor, material forming the upper and the lower electrode needs to be changed as well so that overall performance of the capacitor is improved. A newly developed capacitor having a metal-insulator-metal (MIM) structure is able to boost the performance of a capacitor. This is because the MIM structure has low interfacial reaction.

A conventional method of forming an MIM structure includes, for example, forming a via and a conductive line. Thereafter, deposition, photo-lithographic and etching processes are conducted in sequence to form a lower electrode, a capacitor dielectric layer and an upper electrode. Lastly, a dielectric layer is formed and then another via and conductive line are formed in the dielectric layer.

However, the conventional method of forming the MIM capacitor has some problems. After chemical-mechanical polishing, material layer deposition, photo-lithographic and etching processes, landscape patterns or material image contrast are no longer present to serve as an alignment mask for the metal-insulator-metal capacitor. Consequently, during the alignment of metal-insulator-metal capacitor, extra cleaning operations have to be conducted to align the alignment mask. In addition, two patterning operations are required, one for forming the lower electrode and another for forming the upper electrode. Hence, the production process is more complicated and overall production cost is higher.

### SUMMARY OF THE INVENTION

Accordingly, one object of the present invention is to provide a metal-insulator-metal capacitor and corresponding method of manufacture such that the lower electrode of the capacitor as well as the via are patterned in the same step. Hence, the number of photo-lithographic and etching processes is reduced. Ultimately, the number of production steps and the cost of production are reduced.

A second object of this invention is to provide a metal-insulator-metal capacitor and corresponding method of manufacture such that a damascene process can be used directly, thereby avoiding misalignment problems.

A third object of this invention is to provide a metal-insulator-metal capacitor and corresponding method of manufacture such that the lower electrode of the capacitor has a larger overall surface area and hence the capacitor has a higher capacitance. Surface area is increased by forming a conformal lower electrode over the surface of an opening.

To achieve these and other advantages and in accordance with the purpose of the invention, as embodied and broadly described herein, the invention provides a method of forming a metal-insulator-metal capacitor. First, a substrate is provided and then a first dielectric layer is formed over the substrate. The first dielectric layer is patterned to form a first opening for forming a desired lower electrode and a second opening for forming a desired conductive line. A first metallic layer conformal to the exposed surface of the first opening and completely filling the second opening is formed. A conformal capacitor dielectric layer is formed over the first metallic layer and then a second dielectric layer is formed over the capacitor dielectric layer. The second dielectric layer is patterned to form a third opening above the first opening and a fourth opening above the second opening. The third opening exposes a portion of the capacitor dielectric layer and the fourth opening exposes a portion of the first metallic layer. Finally, a second metallic layer that completely fills the third opening and the fourth opening is formed.

This invention also provides a metal-insulator-metal capacitor. The capacitor comprises a substrate, a conductive line, a first dielectric layer, a lower electrode, a second dielectric layer, an upper electrode and a capacitor dielectric layer. The conductive line is formed over the substrate. The first dielectric layer is formed over the substrate. The lower electrode is embedded within the first dielectric layer and connected with the conductive line. The lower electrode has a concave opening. The second dielectric layer is formed over the first dielectric layer. The upper electrode is formed above the lower electrode and embedded within the second dielectric layer and the concave opening of the lower electrode. The capacitor dielectric layer is formed between the lower electrode and the upper electrode. The lower electrode, the capacitor dielectric layer and the upper electrode together constitute a capacitor. Furthermore, peripheral circuits may also be formed inside the capacitor or conductive lines may also be formed over the capacitor for controlling the capacitor.

One major aspect of this invention is the simultaneous patterning of both the via opening and the desired lower electrode opening in the same operation so that the number of photo-lithographic and etching steps is reduced. Furthermore, a damascene process can be directly used to form the metal-insulator-metal capacitor. Hence, there is no need to perform extra cleaning in preparation for the alignment of the metal-insulator-metal capacitor. Moreover, the conformal layout of the lower electrode over the opening surface increases overall surface area of the capacitor and hence its capacitance.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1D are schematic cross-sectional views showing the progression of steps for producing a metal-insulator-metal capacitor according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

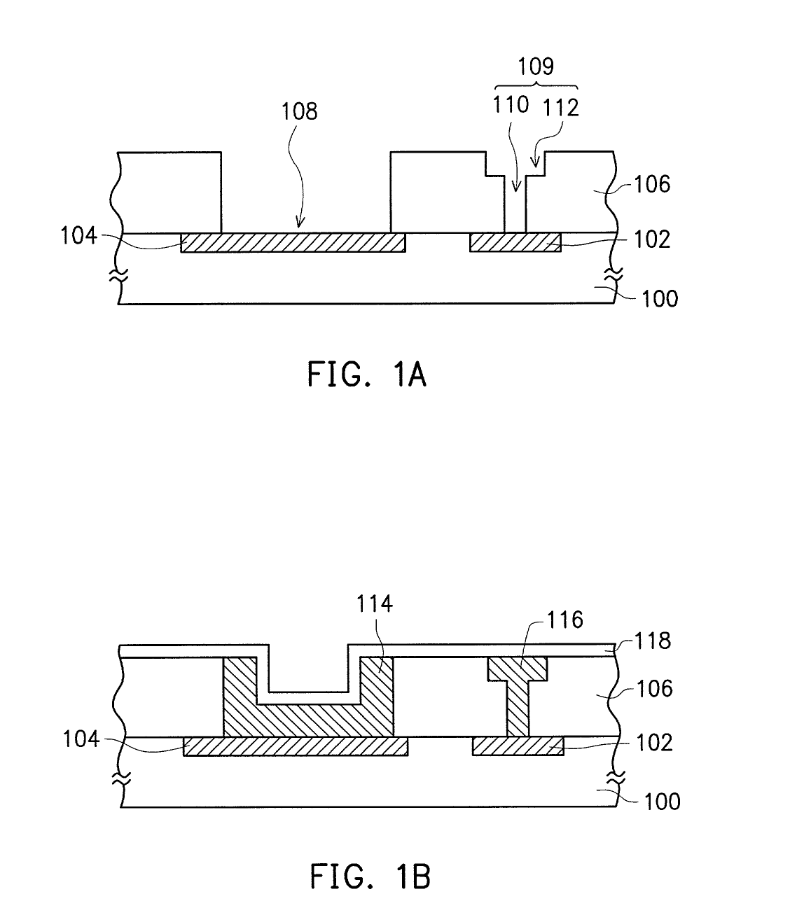

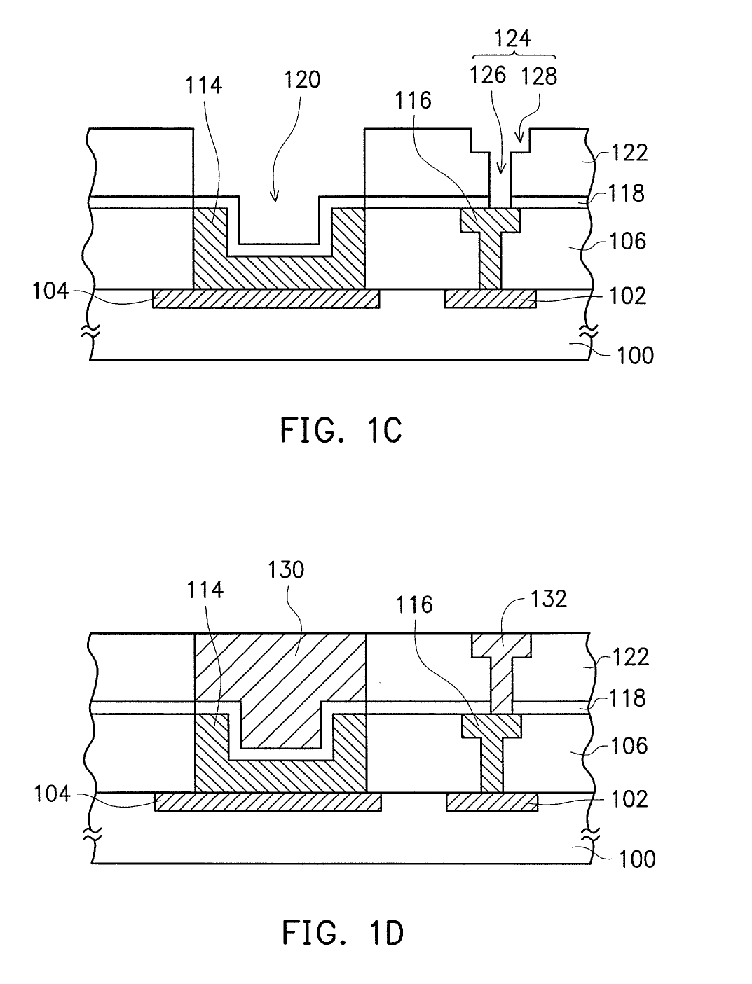

FIGS. 1A through 1D are schematic cross-sectional views showing the progression of steps for producing a metal-insulator-metal capacitor according to one preferred embodiment of this invention. As shown in FIG. 1A, a substrate 100 having a first conductive line 102 and a second conductive line 104 therein is provided. The first conductive line 102 and the second conductive line 104 may connect with a transistor or a peripheral circuit device (not shown), for example. A dielectric layer 106 is formed over the substrate 100. The dielectric layer 106 can be, for example, a silicon oxide, a silicon nitride or a borophosphosilicate glass layer. The dielectric layer 106 is preferably formed, for example, by chemical vapor deposition (CVD). In addition, the dielectric layer 106 can also be a layer formed from, for example, some low dielectric constant material. Thus, the method of forming the dielectric layer 106 varies according to the type of low dielectric constant material chosen. In general, the methods of forming a low dielectric constant material layer include chemical vapor deposition (CVD) and spin coating.

An opening 108 that exposes a portion of the conductive line 104 and an opening 109 that exposes a portion of the conductive line 102 are formed in the dielectric layer 106. The opening 109 can be, for example, an opening for forming a dual damascene opening, a trench for forming a metal line, a via opening for forming a plug, a contact opening or any type of opening for forming a damascene structure (a dual damascene opening is shown in the FIG. 1A). The method of forming the opening 109 includes, for example, performing a trench patterning, a via patterning and a trench and via self-alignment process. For example, an opening 110 that exposes a portion of the conductive line 102 is formed over the dielectric layer 106 above the conductive line 102. A trench 112 is formed in the dielectric layer 106 above the via opening 110. Alternatively, the trench 112 is formed in the dielectric layer 106 above the conductive line. This is followed by forming the dielectric opening 110 that exposes a portion of the conductive line 102 in the dielectric layer 106 under the trench 112. In addition, the opening 108 is formed at the same times as the via opening 110 is patterned. The opening 108 later serves as an opening for forming the lower electrode.

As shown in FIG. 1B, a metallic layer (not shown) is formed over the dielectric layer 106. The metallic layer is conformal to the exposed surface of the opening 108 and fills the opening 109 completely. Material constituting the metallic layer includes, for example, copper, aluminum, palladium or ruthenium. The metallic layer is formed, for example, by chemical vapor deposition, vaporization or magnetron DC sputtering. A portion of the metal outside the openings 108 and 109 is removed to form a lower electrode 114 and an interconnect 116.

A conformal capacitor dielectric layer 118 is formed over the lower electrode 114, the interconnect 116 and the dielectric layer 106. The capacitor dielectric layer 118 can be a dielectric layer having a dielectric constant higher than silicon nitride and silicon oxide such as tantalum pentoxide (Ta₂O₅), barium strontium titanate (BaₓSr(₁₋ₓ) TiO₃) or barium titanate (BaTiO₃). The capacitor dielectric layer 118 is formed, for example, by chemical vapor deposition.

As shown in FIG. 1C, a dielectric layer 122 is formed over the capacitor dielectric layer 118. The dielectric layer 122 can be a silicon oxide layer, a silicon nitride layer or a borophosphosilicate glass layer, for example. The dielectric layer 122 is formed, for example, by chemical vapor deposition. In addition, the dielectric layer 122 can be a low dielectric constant material layer. The method of forming the low dielectric constant material layer depends on the type of dielectric material chosen. In general, chemical vapor deposition or spin coating may be used to form the dielectric material layer.

An opening 120 that exposes a portion of the capacitor dielectric layer 118 is formed in the dielectric layer 122 above the lower electrode 114. The opening 120 serves as an opening for the subsequent formation of an upper electrode. The opening 120 is formed, for example, by performing a photolithographic and an etching process. Another opening 124 that exposes a portion of the interconnect 116 is formed in the dielectric layer 122 above the interconnect 116. The opening 124 may be a damascene opening for forming a dual damascene structure, a trench for forming a conductive line, a via opening for forming a plug, a contact opening for forming a contact or any opening for forming a damascene structure (only a dual damascene opening is shown in FIG. 1D). The opening 124 is formed, for example, by patterning the trench, patterning the via opening and performing a trench and via self-aligned process. For example, a via opening 126 that exposes a portion of the interconnect 116 is formed in the dielectric layer 122 above the interconnect 116. This is followed by the formation of a trench 128 in the dielectric layer 122 above the via opening 126. Alternatively, the trench 128 is formed in the dielectric layer 122 above the interconnect 116 before forming the via opening 126 that exposes a portion of the interconnect 116 in the dielectric layer 122 under the trench 128.

As shown in FIG. 1D, a metallic layer (not shown) is formed over the dielectric layer 122. The metallic layer completely fills the openings 120 and the 124. The metallic layer can be a copper, an aluminum, a palladium or a ruthenium layer formed, for example, by chemical vapor deposition, vaporization or magnetron DC sputtering. A portion of the metal outside the openings 120 and 124 is removed to form an upper electrode 130 and an interconnect 132. The lower electrode 114, the capacitor dielectric layer 118 and the upper electrode 130 together constitute a metal-insulatormetal capacitor.

This invention also provides a metal-insulator-metal capacitor structure whose cross-sectional layout is shown in FIG. 1D. As shown in FIG. 1D, the capacitor structure includes a substrate 100, a conductive line 104, a first dielectric layer 106, a lower electrode 114, a second dielectric layer 122, an upper electrode 130 and a capacitor dielectric layer 118. The conductive line 104 is formed in the substrate 100. The first dielectric layer 106 is formed over the substrate 100. The lower electrode 114 is embedded within the first dielectric layer 106 and connected with the conductive line 104. The lower electrode has a concave opening. The second dielectric layer 122 is formed over the first dielectric layer 106. The upper electrode 130 is formed above the lower electrode 114 and embedded within the second dielectric layer 122 and the concave opening of the lower electrode 114. The capacitor dielectric layer 118 is formed between the lower electrode 114 and the upper electrode 130. The lower electrode 114, the capacitor dielectric layer 118 and the upper electrode 130 together constitute a capacitor.

One major advantage of this invention is the simultaneous patterning of both the via opening and the desired lower electrode opening so that the number of photolithographic and etching steps is reduced. Furthermore, a damascene process can be directly used to form the metal-insulator-metal capacitor. Since no extra cleaning in preparation for the alignment of the metal-insulator-metal capacitor is required, fewer processing steps are needed and production cost is thereby saved. Moreover, the conformal layout of the lower electrode over the opening surface increases overall surface area of the capacitor and hence its capacitance.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a metal-insulator-metal capacitor, comprising:
providing a substrate;
forming a first dielectric layer over the substrate;
patterning the first dielectric layer to form a first opening for forming a desired lower electrode and a second opening for forming a desired interconnect;
forming a first metallic layer over the substrate, wherein the first metallic layer is conformal to a surface of the first opening and also completely fills the second opening;
removing a portion of the first metallic layer from the first opening and the second opening so that a lower electrode is formed in the first opening and a first interconnect is formed in the second opening;
forming a conformal capacitor dielectric layer over the substrate;
forming a second dielectric layer over the capacitor dielectric layer;
patterning the second dielectric layer to form a third opening above the lower electrode, wherein the third opening exposes a portion of the capacitor dielectric layer;
patterning the second dielectric layer to form a fourth opening above the first interconnect, wherein the fourth opening exposes a portion of the first interconnect;
forming a second metallic layer over the second dielectric layer such that the third opening and the fourth opening are completely filled; and
removing a portion of the second metallic layer outside the third opening and the fourth opening so that an upper electrode is formed in the third opening and a second interconnect is formed in the fourth opening.

2. The method of claim 1, wherein a material forming the first metallic layer and the second metallic layer is selected from a group consisting of copper, aluminum, palladium and ruthenium.

3. The method of claim 1, wherein a method of forming the first metallic layer and the second metallic layer is selected from a group consisting of chemical vapor deposition, evaporation and magnetron DC sputtering.

4. The method of claim 1, wherein a material forming the capacitor dielectric layer is selected from a group consisting of tantalum pentoxide, barium-strontium-titanate and barium titanate.

5. The method of claim 1, wherein forming the capacitor dielectric layer includes chemical vapor deposition.

6. The method of claim 1, wherein removing a portion of the first metallic layer outside the first opening and the second opening and removing a portion of the second metallic layer outside the third opening and the fourth opening includes performing chemical-mechanical polishing.

7. The method of claim 1, wherein the second opening and the fourth opening are both a type of opening selected from a group consisting of a dual damascene opening for forming a dual damascene structure, a trench for forming a conductive line, a via opening for forming a plug, a contact opening for forming a contact and any opening for forming a damascene structure.

8. The method of claim 1, wherein the second opening includes a via opening for forming a desired plug.

9. The method of claim 8, wherein the method further includes forming a trench in the first dielectric layer such that the trench exposes the via opening.

10. The method of claim 1, wherein the second opening includes a via opening for forming a plug.

11. The method of claim 10, wherein before forming the first opening and the second opening, a trench is further formed in the first dielectric layer for housing a conductive line.

12. A method of forming a metal-insulator-metal capacitor, comprising:
providing a substrate;
forming a first dielectric layer over the substrate;
patterning the first dielectric layer to form a first opening and a first via opening;
patterning the first dielectric layer to form a first trench, wherein the first trench exposes the first via opening;
forming a first metallic layer over the first dielectric layer, wherein the first metallic layer is conformal to a surface of the first opening and also completely fills the first trench;
removing a portion of the first metallic layer until an upper surface of the first dielectric layer is exposed so that remaining first metallic layer inside the first opening forms a lower electrode and remaining first metallic layer in the first via opening and the first trench together form a first interconnect;
forming a conformal capacitor dielectric layer over the substrate;
forming a second dielectric layer over the capacitor dielectric layer;
patterning the second dielectric layer to form a second opening that exposes a portion of the capacitor dielectric layer, wherein the second opening is formed directly above the first opening;
patterning the second dielectric layer to form a second via opening that exposes a portion of the first metallic layer;
patterning the second dielectric layer to form a second trench, wherein the second trench exposes the second via opening;
forming a second metallic layer that completely fills the second opening, the second via opening and the second trench; and
removing a portion of the second metallic layer until an upper surface of the second dielectric layer is exposed so that an upper electrode is formed inside the second opening and a second interconnect is formed inside the second via opening and the second trench.

13. The method of claim 12, wherein a material forming the first metallic layer and the second metallic layer is selected from a group consisting of copper, aluminum, palladium and ruthenium.

14. The method of claim 12, wherein a method of forming the first metallic layer and the second metallic layer is selected from a group consisting of chemical vapor deposition, evaporation and magnetron DC sputtering.

15. The method of claim 12, wherein a material forming the capacitor dielectric layer is selected from a group consisting of tantalum pentoxide, barium-strontium-titanate and barium titanate.

16. The method of claim 12, wherein forming the capacitor dielectric layer includes chemical vapor deposition.

17. The method of claim 12, wherein removing a portion of the first metallic layer and removing a portion of the second metallic layer includes performing chemical-mechanical polishing.

18. A metal-insulator-metal capacitor, comprising:
a substrate having a conductive line thereon;
a first dielectric layer over the substrate;
a lower electrode embedded within the first dielectric layer and connected with the conductive line in the substrate, wherein the lower electrode further has a concave opening;
a second dielectric layer over the first dielectric layer;
an upper electrode above the lower electrode embedded within the second dielectric layer and inside the concave opening of the lower electrode; and
a capacitor dielectric layer between the lower electrode and the upper electrode.

19. The capacitor of claim 18, wherein a material forming the upper electrode and the lower electrode is selected from a group consisting of copper, aluminum, palladium and ruthenium.

20. The capacitor of claim 18, wherein a material forming the capacitor dielectric layer is selected from a group consisting of tantalum pentoxide, barium-strontium-titanate and barium titanate.
